(19) United States
(12) Patent Application Publication
(10) Pub. No.: US 2002/0177254 A1
(43) Pub. Date: Nov. 28, 2002

(54) Semiconductor package and method for making the same

(76) Inventors: Wai Wong Chow, Tai Po (HK); Fei Ying Wong, Tung Chung Crescent (HK); Man Hon Cheng, Hong Kong (HK)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/118,986

(22) Filed: Apr. 9, 2002

Related U.S. Application Data
(62) Division of application No. 09/702,563, filed on Oct. 31, 2000, now abandoned.

(51) Int. Cl. H01L 21/44; H01L 21/48; H01L 21/50

(52) U.S. Cl. 438/107; 438/118; 438/106; 438/127

(57) ABSTRACT

A QFN semiconductor package (2) having a plurality of connection pads (4) and an embedded die (10) is disclosed. The connection pads (4) at least partially enclose a die receiving area (6). An insulator (8) is disposed in the die receiving area (6). The die (10) is attached to the insulator (8). The die (10) has a plurality of die bond pads. A plurality of connectors (12) connects the die bond pads to respective connection pads (4). An encapsulant (14) at least partially encapsulates the connection pads (4), insulator (8) and die (10). The connection pads (4) and insulator (8) have exposed surfaces on an outer surface of the encapsulant (14). The exposed surfaces are substantially co-planar with the outer surface of the encapsulant (14). A method of producing the semiconductor package (2) is also disclosed. Preferably, the insulator (8) includes a dispensed epoxy layer that is curable after the die is attached.

### FIELD OF THE INVENTION

This invention relates generally to semiconductor packages, and more particularly to semiconductor packages and methods of making Quad Flat No-lead (QFN) semiconductor packages.

### BACKGROUND ART

There are many types of semiconductor packages. In U.S. Pat. No. 5,894,108 there is disclosed a semiconductor package that is similar to QFN packages. The semiconductor package incorporates a leadframe that includes a plurality of leads radially aligned around a central opening. A die is mounted in the central opening and is electrically connected to the leads by bonding wires. An encapsulant is formed over the die, wires and leads to encapsulate the package. Surfaces of the die and leads are exposed through the encapsulant. These surfaces are co-planar with an outer surface of the encapsulant.

Such a package suffers from several disadvantages. The die is usually of a brittle material and the exposed unprotected die is prone to damage during handling of the package. The exposed die also prevents conductive traces from being run on a PCB surface directly beneath an exposed die of a mounted package, thereby restricting the PCB area on which conductive traces can be run. The routing density of the PCB is thus limited.

One way of protecting the die from damage is to simply embed the die in the encapsulant. A simple solution would be to provide a leadframe that includes an upset-formed flag portion for mounting the die. In producing such a leadframe, an additional step is required to raise or offset the flag portion. Such a leadframe is therefore more expensive to produce. This leadframe with an offset flag portion is more likely to also result in a semiconductor package that is thicker than one that is manufactured from a flat leadframe.

### SUMMARY OF THE INVENTION

According to one aspect of the invention there is provided a semiconductor package having a plurality of connection pads at least partially enclosing a die receiving area. An insulator is disposed in said die receiving area. A die is attached to said insulator, said die having a plurality of die bond pads connected to respective ones of said plurality of connection pads.

An encapsulant at least partially covers said connection pads and insulator. Said connection pads and insulator have exposed surfaces that are substantially co-planar with an outer surface of said encapsulant.

Preferably said insulator should be thinner than said plurality of connection pads.

Suitably, said insulator may be an epoxy layer and said die may be directly attached to said epoxy layer.

Preferably, said epoxy layer should be dispensed and cured to secure the die.

Suitably, said connection pads may be leads of a singulated leadframe.

According to another aspect of the invention there is provided a method for producing said semiconductor package described above. The method includes providing a plurality of connection pads on a removable substrate, said connection pads at least partially enclosing a die receiving area. The method further includes disposing an insulator in said die receiving area and attaching a die to said insulator, said die having die bond pads.

The method also includes electrically connecting said die bond pads to respective ones of said plurality of connection pads. Finally, the method includes at least partially encapsulating said plurality of connection pads, insulator and die with an encapsulant such that surfaces on said plurality of connection pads and insulator are exposed on an outer surface of said encapsulant.

Preferably, the method may further include removing said removable substrate from said semiconductor package.

Preferably, said exposed surfaces may be substantially coplanar with said outer surface of said encapsulant.

Suitably, providing a plurality of connection pads on a removable substrate may include providing a plurality of connection pads on a layer of adhesive tape.

Preferably, placing an insulator in said die receiving area may include dispensing epoxy in said die receiving area and attaching a die may include attaching a die directly to said epoxy and curing said epoxy to secure said die.

Preferably, said epoxy should be thinner than said plurality of connection pads.

Suitably, providing a plurality of connection pads on a removable substrate may include providing a leadframe having a plurality of leads supported by tie bars on a removable substrate and the method further includes separating said plurality of leads from said tie bars.

### BRIEF DESCRIPTION OF THE DRAWINGS

In order that the invention may be readily understood and put into practical effect, reference will now be made to a preferred embodiment as illustrated with reference to the accompanying drawings in which:

FIG. 1 is a cross sectional view of a semiconductor package according to the present invention;

FIG. 2A is a top isometric view of a leadframe panel having a plurality of leadframes with leads that at least partially enclose a die receiving area;

FIG. 2B is a top isometric view showing the leadframe panel in FIG. 2A provided on an adhesive tape;

FIG. 2C is a top isometric view similar to FIG. 2B further showing epoxy being dispensed on the adhesive tape in the die receiving areas;

FIG. 2D is similar to FIG. 2C further showing dies being attached to the dispensed epoxy.

FIG. 2E is a top isometric view of a mould placed over the leadframe panel in FIG. 2D for forming an encapsulant over each die and leadframe assembly in FIG. 2D.

FIG. 2F is an underside isometric view showing the adhesive layer being removed from the leadframe panel.

FIG. 3 is an underside isometric view of a completed semiconductor package produced according to the assembly process illustrated in FIGS. 2A-2F.

### DETAILED DESCRIPTION OF A PREFERRED EMBODIMENT OF THE INVENTION

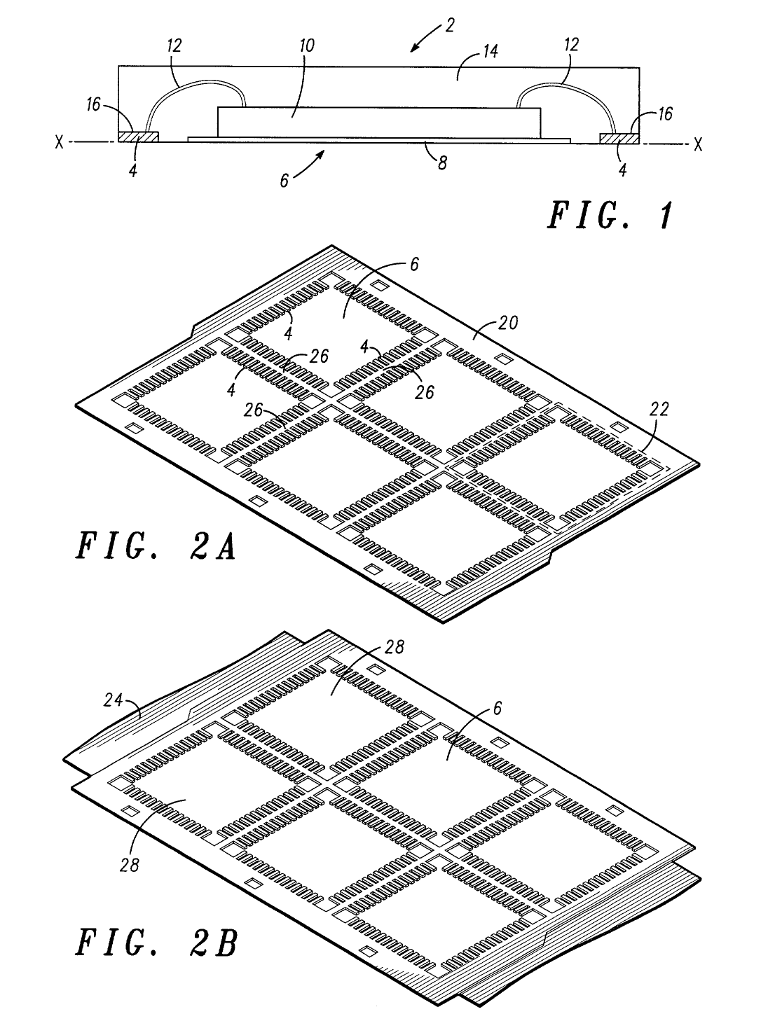

FIG. 1 is a cross sectional view of a semiconductor package 2 according to an embodiment of the present invention. This semiconductor package 2 has a plurality of connection pads 4. The connection pads 4 at least partially enclose a die receiving area 6. An insulator 8 is disposed in the die receiving area 6. A semiconductor die 10 is attached to the insulator 8. Die bond pads (not shown) on the semiconductor die 10 are connected to respective ones of the plurality of connection pads 4 using connectors such as bonding wires 12. The die bond pads (not shown) are electrically connected to electrical circuits implemented on the semiconductor die 10. An encapsulant 14 at least partially encloses the connection pads 4, insulator 8, semiconductor die 10 and bonding wires 12.

Each connection pad 4 of the plurality of connection pads 4 has a surface 16 that is exposed to allow external electrical connection, for example to pads of a printed circuit board. The insulator 8 also has a surface that is exposed. The exposed surfaces are substantially coplanar with the outer surface of the encapsulant 14 to define a common plane as shown by line X-X in FIG. 1. Preferably, the insulator 8 is a layer of dispensable and curable epoxy. However other suitable materials known to those skilled in the art may be used. Such materials include liquid encapsulant and film-based epoxy or adhesive. These materials should adhere to the encapsulant 14. The epoxy layer 8 is preferably thinner than the connection pads 4 so as to keep the overall thickness of the semiconductor package 2 to a minimum.

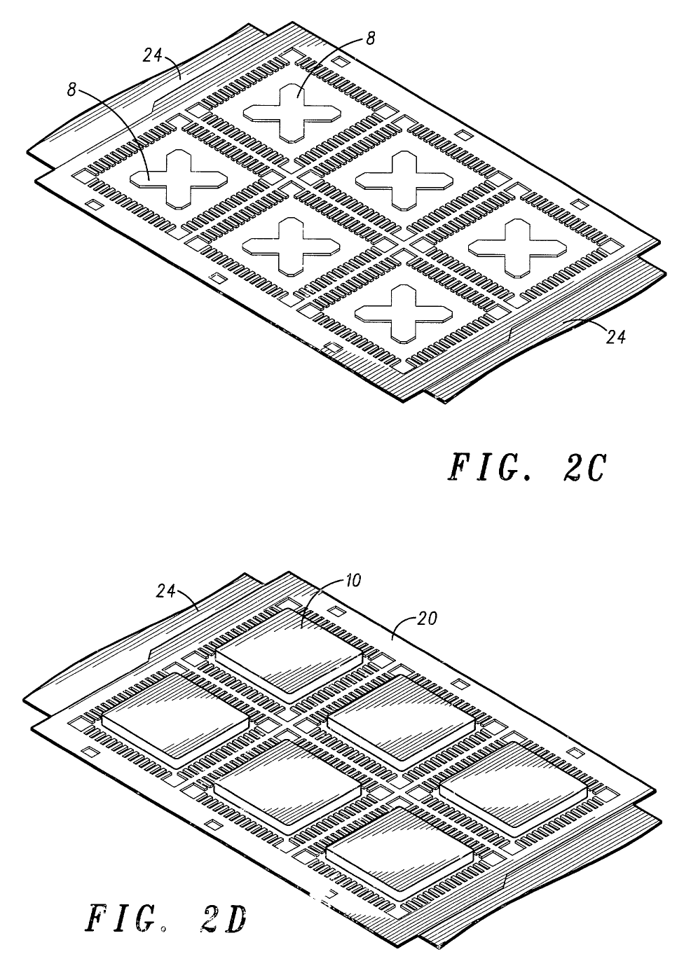

FIGS. 2A-2F describe a method or process of assembling the semiconductor package 2. Preferably a leadframe panel 20 having a plurality of leadframes 22 is used to provide the connection pads 4. The leadframe panel 20 is formed from a thin metal (e.g. copper) sheet which has been etched, cut or stamped to form a pattern similar to that shown in FIG. 2A. This leadframe panel 20 may be readily provided on a removable substrate 24 as shown in FIG. 2B or the leadframe panel 20 may be attached to the removable substrate 24 during the assembly process. Each leadframe 22, shown in dotted lines, of the plurality of leadframes 22 has a plurality of connection pads or leads 4 that at least partially enclose a die receiving area 6. In this particular embodiment, the leads 4 surround the die receiving area 6. Tie bars 26 support the leads 4 and connect the individual leadframes 22 on the panel 20. FIG. 2B shows the leadframe panel 20 provided on the removable substrate 24. Preferably the removable substrate 24 is a transparent adhesive tape 24 such as polyimide with an adhesive layer. Other substrates may also be used, such as any flexible organic or metallic substrate or a combination of the two. These substrates should be provided with a layer of bonding material. This layer of bonding material should preferably remain attached to the substrate when the substrate is removed from a surface. The purpose of the adhesive tape 24 is to support the die 10 and the leadframe panel 20 during the assembly process, and to maintain the die 16 in a proper location relative to an associated leadframe 22. Specifically, one surface of the leadframe panel 20 comes into contact with a sticky surface of the adhesive tape 24. A central portion 28 of the adhesive tape 24 remains exposed through the die receiving area 6 of each leadframe 22.

An insulator 8 is next disposed on the exposed central portion 28 of the adhesive tape 24 as shown in FIG. 2C. The sticky surface supports the leadframe 22 and the insulator 8 such that supported surfaces of the leadframe 22 and insulator are substantially co-planar.

Referring to FIG. 2D, a semiconductor die 10 is next attached to the insulator 8 to be held substantially securely during the assembly process. With epoxy as the insulator 8, the die 10 can be attached directly to the epoxy before curing the epoxy in a conventional baking process. The cured epoxy secures the die in place. The amount of epoxy that is dispensed is preferably controlled such that the epoxy is sufficient to substantially cover the surface of the die 10 and at the same time allow the overall semiconductor package 2 to be relatively thin. Preferably, the epoxy is filled with spacer particles to ensure a minimum thickness of the epoxy for insulating the die 10.

Next, connectors (shown only in FIG. 1) such as bonding wires 12 are used to electrically connect die bond pads on the die 10 to respective leads 4 using known wire bonding techniques.

Subsequent to wire bonding, an encapsulant 14 such as a molded plastic casing is used to at least partially encapsulate the leads 4, insulator 8 and die 10 using known plastic molding techniques while each leadframe 22 and associated insulator 8 remain mounted on the adhesive tape 24. FIG. 2E shows an example of an array molding technique for encapsulating semiconductor packages. During the molding process, liquefied curable plastics material flows onto exposed portions of the adhesive tape 24 which are located between the die 10 and the leads 4, and in between the leads 4. After encapsulation, the adhesive tape 24 is removed from the leadframe panel 20 as shown in FIG. 2F. Subsequently, the tie bars 26 are removed by sawing or trimming to singulate the individual semiconductor packages 2.

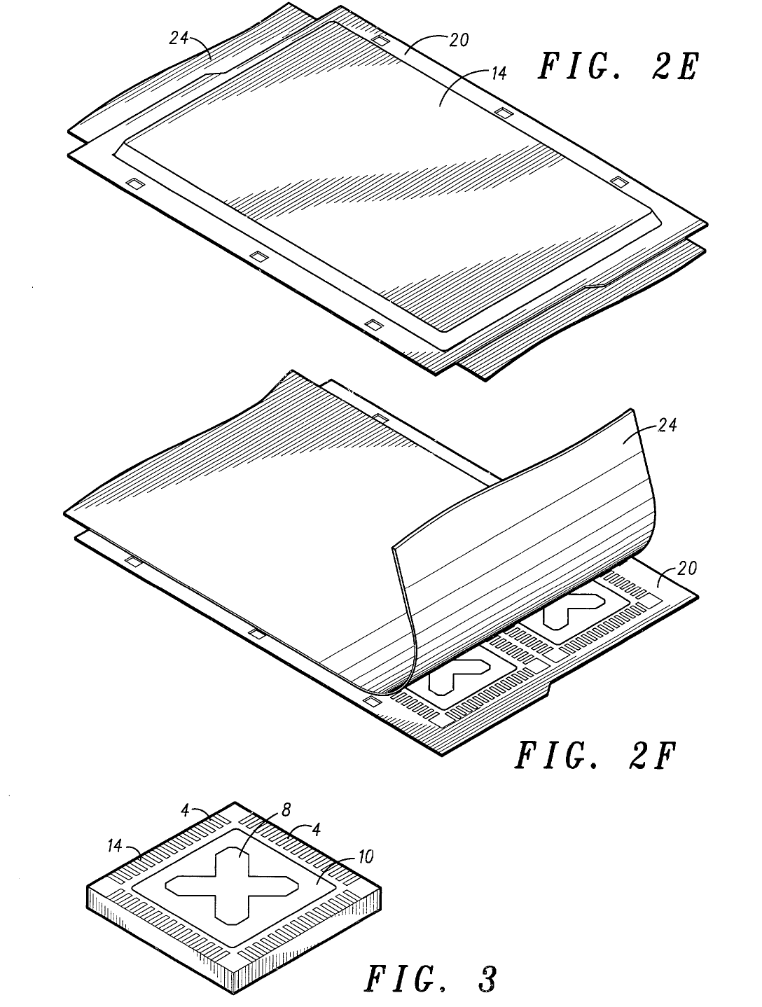

The semiconductor package 2 produced by the above assembly process has leads 4 and insulator 8 surfaces that are exposed on an outer surface of the encapsulant 14. These surfaces are substantially co-planar as shown on an underside of the semiconductor package 2 in FIG. 3.

Advantageously, such a semiconductor package 2 has an insulator 8 that protects a surface of the die 10 thereby allowing conductive traces to be run on a surface of a PCB directly beneath a mounted package without electrically shorting the traces. The package 2 also has exposed connection pad surfaces and insulator surface that are co-planar with an outer surface of an encapsulant 14 that allows the semiconductor package 2 to be economically manufactured.

Although the invention has been described with reference to a preferred embodiment, it is to be understood that the invention is not restricted to the embodiment described herein. For example, it should be noted that the leadframe 22 shown in FIG. 2A is simplified for ease of illustration. A leadframe 22 used in an actual semiconductor package may have a different shape than that shown and it typically includes many more leads.

As another example, the steps of mounting the leadframe 22 and the insulator 8 may be reversed. Also, glob top material may be used in place of the molded plastic casing. Similarly, the adhesive tape 24 may be removed after singulation.

We claim:

1. A semiconductor package comprising:
a plurality of connection pads at least partially enclosing a die receiving area;
an insulator disposed in said die receiving area;
a die attached to said insulator, said die having a plurality of die bond pads connected to respective ones of said plurality of connection pads;
an encapsulant at least partially covering said connection pads and insulator;
wherein said connection pads and insulator have exposed surfaces that are substantially co-planar with an outer surface of said encapsulant.

2. A semiconductor package according to claim 1, wherein said insulator is thinner than said connection pads.

3. A semiconductor package according to claim 1, wherein said insulator is an epoxy layer and wherein said die is directly attached to said epoxy layer.

4. A semiconductor package according to claim 3, wherein said epoxy layer is dispensed and cured to secure the die.

5. A semiconductor package according to claim 1, wherein said connection pads are leads of a singulated leadframe.

6. A method of producing a semiconductor package, said method comprising:
providing a plurality of connection pads on a removable substrate, said connection pads at least partially enclosing a die receiving area;
disposing an insulator in said die receiving area;
attaching a die to said insulator, said die having die bond pads;
electrically connecting said die bond pads to respective ones of said plurality of connection pads; and
at least partially encapsulating said plurality of connection pads, insulator and die with an encapsulant such that surfaces on said plurality of connection pads and insulator are exposed on an outer surface of said encapsulant.

7. A method according to claim 6, further comprising removing said removable substrate from said semiconductor package.

8. A method according to claim 6, wherein said exposed surfaces are substantially co-planar with said outer surface of said encapsulant.

9. A method according to claim 6, wherein providing a plurality of connection pads on a removable substrate includes providing a plurality of connection pads on a layer of adhesive tape.

10. A method according to claim 6, wherein placing an insulator in said die receiving area includes dispensing epoxy in said die receiving area and wherein attaching a die includes attaching a die directly to said epoxy and curing said epoxy to secure said die.

11. A method according to claim 10, wherein said epoxy is thinner than said plurality of connection pads.

12. A method according to claim 6, wherein providing a plurality of connection pads on a removable substrate includes providing a leadframe having a plurality of leads supported by tie bars on a removable substrate and the method further including separating said plurality of leads from said tie bars.
